(19) United States
(12) Patent Application Publication
(10) Pub. No.: US 2014/0191410 A1
(43) Pub. Date: Jul. 10, 2014

(54) DAMAGE MONITOR STRUCTURE FOR THROUGH-SILICON VIA (TSV) ARRAYS

(71) Applicants: Gerald S. Leatherman, Portland, OR (US); Christopher C. Pelto, Beaverton, OR (US)

(72) Inventors: Gerald S. Leatherman, Portland, OR (US); Christopher C. Pelto, Beaverton, OR (US)

(21) Appl. No.: 13/977,595

(22) PCT Filed: Dec. 27, 2011
(86) PCT No.: PCT/US11/67363

§ 371 Date: Mar. 19, 2014

(51) Int. Cl. H01L 21/66; H01L 21/768; H01L 23/48

(52) U.S. Cl. CPC H01L 22/14; H01L 23/481; H01L 21/76877
USPC 257/774; 438/17

(57) ABSTRACT

Described herein are techniques related to techniques for monitoring damage to circuitry or structure neighboring one or more through-silicon vias (TSVs) caused by TSV-related processing. Additionally, techniques for confining diffusion of moisture or chemical from one or more TSVs during TSV-related processing are also described. This Abstract is submitted with the understanding that it will not be used to interpret or limit the scope or meaning of the claims.

### BACKGROUND

The evolution of integrated circuits (ICs), also known as chips, has seen a constant push for higher speed, less power consumption and small footprint. The prevalence of handheld, portable electronic devices further drives the demand for chips of small form factor with low power consumption. Three-dimensional integrated circuits (3D ICs) are emerging as a way to overcome interconnect scaling issues in two-dimensional ICs (2D ICs) and have smaller footprint than 2D ICs. Through-silicon via (TSV) is an enabling technology for 3D integration of multiple dies/wafers, whether fabricated by the same process or different processes, into a single stack. TSVs may be formed before the IC is completed, i.e., “via-last” approach, or after the IC is completed, i.e., “via-first” approach.

Under the via-last approach, TSVs are formed after the dies have been processed to form the circuitry of the IC. For example, circuitry is first patterned and completed on the front side of a silicon wafer. The wafer is then flipped over and TSVs are formed by etching through the wafer from the back side of the wafer. However, the process that etches TSVs into a wafer having preexisting circuitry or previously fabricated structures may result in damage to neighboring circuitry or structures. More specifically, chemicals or moisture may diffuse from the TSVs to the surrounding region due to etching, cleaning, plating, or other TSV-related processing. This risk is particularly high for high aspect ratio TSVs, which typically require a significant over etch to accommodate process variations. The damage may not be immediately detectable if the neighboring circuitry is redundant or not critical to function of the final product, and may result in product failure during customer usage due to crack propagation or additional contaminant diffusion.

### BRIEF DESCRIPTION OF THE DRAWINGS

FIG. 1 is a diagram illustrating an example scheme implementing a through silicon via (TSV) damage monitor and a TSV guard ring.

FIG. 2 is a diagram illustrating an example section of a through-silicon via (TSV) TSV damage monitor.

FIG. 3 is a diagram illustrating a cross-sectional view of a semiconductor structure having a through-silicon via (TSV) TSV guard ring embedded therein.

FIG. 4 is a diagram illustrating cross-sectional views of through-silicon via (TSV), a TSV damage monitor, and a TSV guard ring according to the example scheme of FIG. 1.

FIG. 5 is a flow chart illustrating an example method for monitoring damage to circuitry or structure neighboring one or more through-silicon via (TSVs) caused by TSV-related processing using a TSV damage monitor.

FIG. 6 is a flow chart illustrating an example method for forming a through-silicon via (TSV) guard ring against diffusion of moisture or chemical from one or more TSVs during TSV-related processing.

The Detailed Description references the accompanying figures. In the figures, the left-most digit(s) of a reference number identifies the figure in which the reference number first appears. The same numbers are used throughout the drawings to reference like features and components.

### DETAILED DESCRIPTION

Disclosed herein are devices, structures and methods that implement (1) techniques for monitoring damage to circuitry or structure neighboring one or more through-silicon via (TSV) caused by TSV-related processing, and (2) techniques for confining diffusion of moisture or chemical from one or more TSVs during TSV-related processing.

In some embodiments, a TSV damage monitor including an electrically conductive chain is formed and embedded in a semiconductor structure on which circuitry and one or more TSVs are formed. The TSV damage monitor is formed before the one or more TSVs are formed, and is formed around a TSV region through which the one or more TSVs will traverse. An electrical property related to the TSV damage monitor is measured before and after forming the one or more TSVs, and existence of damage is detected when the measured electrical property is changes. The measured electrical property may be, for example, the resistance of the TSV damage monitor or the leakage current between the TSV damage monitor and the semiconductor structure, or both the resistance and leakage current.

In some embodiments, a TSV guard ring is formed and embedded in a semiconductor structure on which circuitry and one or more TSVs are formed. The TSV guard ring is formed before the one or more TSVs are formed, and is formed around a TSV region through which the one or more TSVs will traverse.

Example Scheme

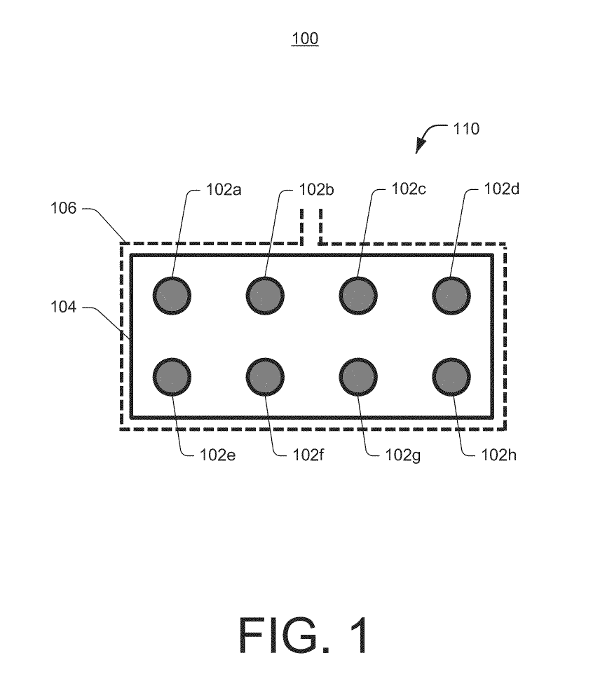

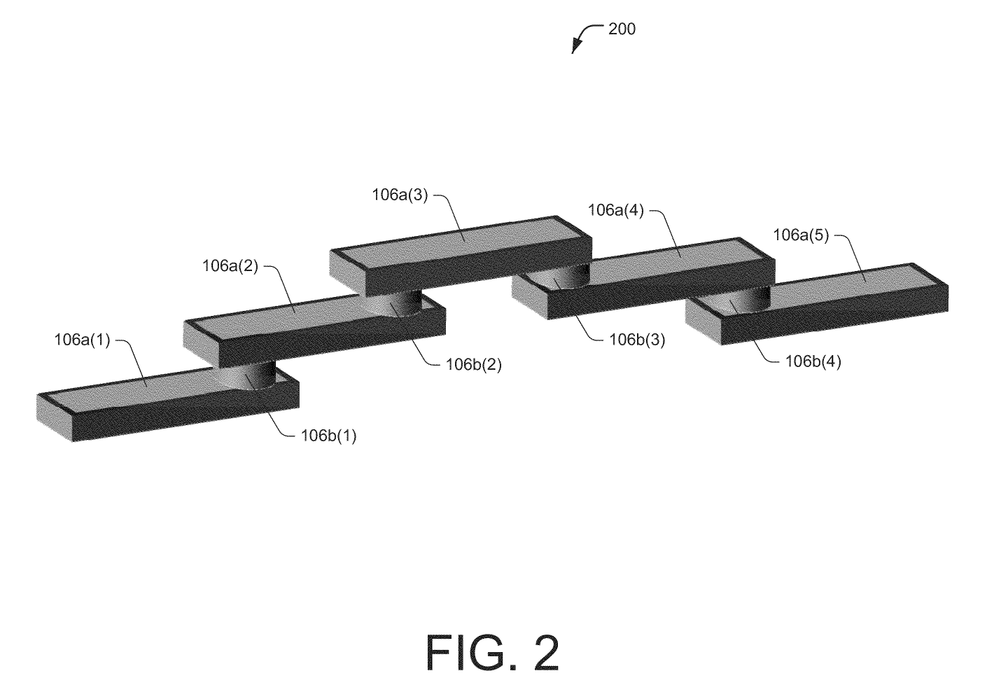

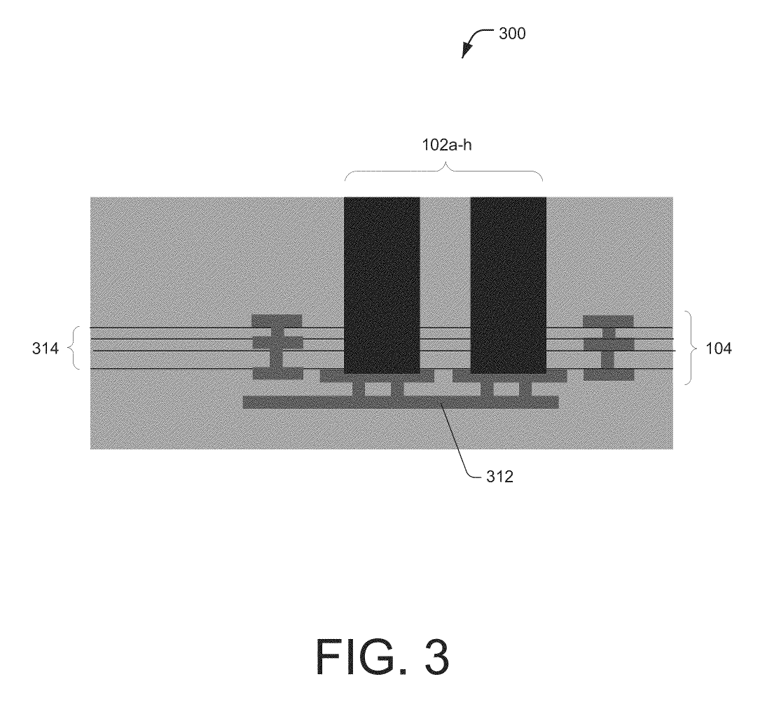

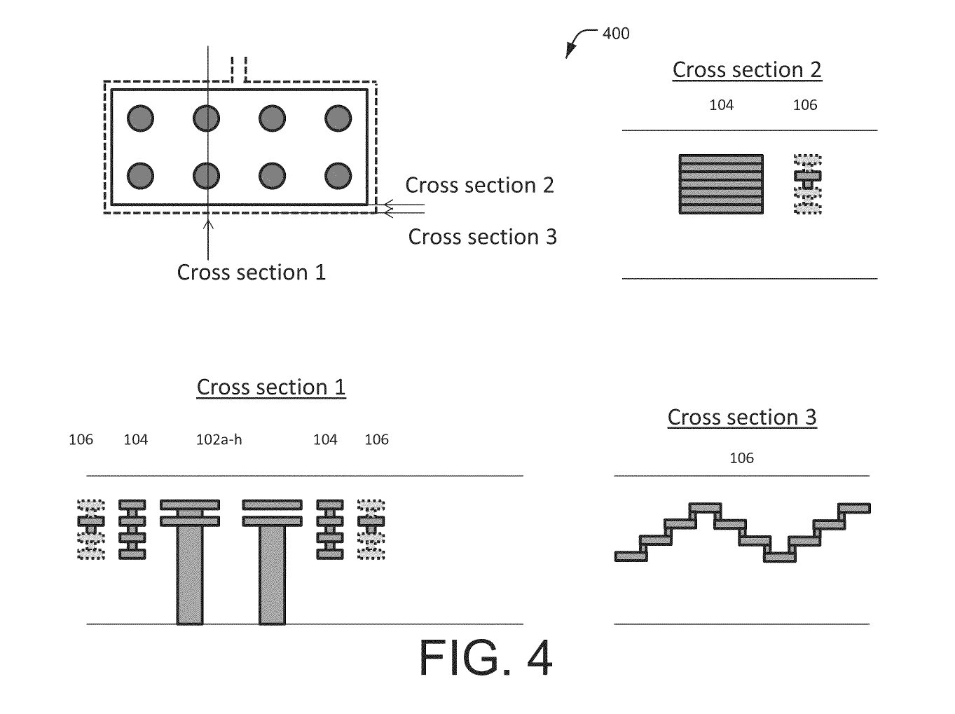

FIG. 1 illustrates an example scheme 100 that implements a TSV damage monitor and a TSV guard ring in a multi-layer semiconductor structure. FIG. 2 illustrates an example section of a TSV damage monitor. FIG. 3 illustrates a cross-sectional view of a semiconductor structure having a TSV guard ring embedded therein. FIG. 4 illustrates cross-sectional views 400 of TSVs, a TSV damage monitor, and a TSV guard ring according to the example scheme of FIG. 1. The description that follows refers to FIGS. 1-4.

In the scheme 100, region 110 of a multi-layer semiconductor structure or device, e.g., a 3D IC, is a region through which one or more TSVs 102a-h that traverse through the multi-layer semiconductor structure may he formed. Although a set number of TSVs are shown in FIG. 1, those of ordinary skill in the art would appreciate that in various implementations the actual number of TSVs may vary between 1 and any number greater than 1.

In at least one embodiment, a TSV damage monitor 106 may he formed around the region 110, hereinafter referred to as the “TSV region”. In at least one embodiment, a TSV guard ring 104 may be formed around the TSV region 110. In at least one embodiment, both the TSV damage monitor 106 and the TSV guard ring 104 may be formed around the TSV region 110 as depicted in FIG. 1. In the case that both the TSV damage monitor 106 and the TSV guard ring 104 are formed around the TSV region 110, the TSV guard ring 104 is formed between the TSV damage monitor 106 and the one or more TSVs 102a-h.

The TSV damage monitor 106 may comprise an electrically conductive chain that includes a plurality of metal lines 106a(1)-(n) and a plurality of vias 106b(1)-(n). Each of the vias 106b(1)-(n) couples respective two of the metal lines 106a(1)-(n) such that the metal lines 106a(1)-(n) are electrically coupled in series to form a series resistor.

The plurality of metal lines 106a(1)-(n) of the TSV damage monitor 106 may be made of the same metallic material used in the metal layer of the multi-layer semiconductor structure. Alternatively, the metal lines of the TSV damage monitor 106 may be made of a metal different from the metallic material used in the metal layer of the multi-layer semiconductor structure. In some embodiments, the plurality of metal lines 106a(1)-(n) may be made of copper.

In some embodiments, the TSV damage monitor 106 may be formed when the front-side circuitry on the multi-layer semiconductor structure is formed. In some embodiments, the TSV damage monitor 106 may be formed in those layers of the multi-layer semiconductor structure through which the one or more TSVs 102a-h will be formed. The TSV region 110, where the one or more TSVs 102a-h will be formed to traverse through the multi-layer semiconductor structure, is determined in advance so that the TSV damage monitor 106 may be formed and located in proximity to the one or more TSVs 102a-h.

FIG. 2 shows a section 200 of the electrically conductive chain of the TSV damage monitor 106. In some embodiments, the metal lines 106a(1)-(n) forming the electrically conductive chain of the TSV damage monitor 106 may be coupled by the vias 106b(1)-(n) in a staircase-like or wave-like manner The metal lines 106a(1)-(n) are thereby embedded in each layer of the multi-layer semiconductor structure through which the one or more TSVs 102a-h are fabricated.

The TSV damage monitor 106 may be used to detect the existence of damage to circuitry or structure of the multi-layer semiconductor structure neighboring the one or more TSVs 102a-h due to diffusion of moisture or chemicals because of TSV-related processing. That is, whether or not damage to a portion of the multi-layer semiconductor structure was induced during a process of forming the one or more TSVs 102a-h may be determined based on one or more electrical properties related to the electrically conductive chain of the TSV damage monitor 106. In some embodiments, a first value of an electrical property of the electrically conductive chain of the TSV damage monitor 106 may be measured before forming the one or more TSVs 102a-h. A second value of the electrical property of the electrically conductive chain of the TSV damage monitor 106 may be measured again after the one or more TSVs 102a-h are formed. Existence of any such damage may be detected when the second value of the measured electrical property is different than the first value, in certain implementations, a single measurement may be performed after the TSV is formed and the electrical value compared to a reference value to determine whether there is damage.

In some embodiments, the measured electrical property may be the resistance of the electrically conductive chain of the TSV damage monitor 106. In other embodiments, the measured electrical property may be the leakage current between the electrically conductive chain of the TSV damage monitor 106 and a silicon substrate of the multi-layer semiconductor structure. If the TSV guard ring 104 is in place, the measured electrical property may be the leakage current between the electrically conductive chain of the TSV damage monitor 106 the TSV guard ring 104. Alternatively, the measured electrical property may be both the resistance and the leakage current as described above.

The TSV guard ring 104 may comprise a metal-and-via stack that encompasses the one or more TSVs 102a-h. The TSV guard ring 104 may include one or more continuous lines of metal formed and embedded in one or more layers of the multi-layer semiconductor structure, and may further include one or more continuous lines of trench vias formed and embedded in one or more layers of the multi-layer semiconductor structure. As shown in FIG. 3, the TSV guard ring 104 is formed in layers 314 of the multi-layer semiconductor structure 300 and in proximity of the one or more TSVs 102a-h that are connected to circuitry 312.

The continuous lines of metal and the continuous lines of trench vias are stacked alternatingly such that a continuous line of trench via is stacked between two continuous lines of metal, and vice versa. For example, a continuous line of metal may be embedded in a first layer of the multi-layer semiconductor structure while a continuous line of trench via may be embedded in a second layer of the multi-layer semiconductor structure that is adjacent the first layer. The one or more continuous lines of metal and the one or more continuous lines of trench vias are stacked to form a metal-and-via stack, or wall, one all layers of the multi-layer semiconductor structure through which the one or more TSVs 102a-h are formed, as depicted in FIG. 3. In other words, the TSV guard ring 104 is a barrier encompassing the TSV region 110, and hence the one or more TSVs 102a-h, to hermetically seal the TSV region 110 to confine moisture, contaminants and chemicals that may diffuse from the one or more TSVs 102a-h during TSV-related processing, such as etching, cleaning, plating, and so forth.

The one or more continuous lines of metal of the TSV guard ring 104 may be made of the same metallic material used in the metal layer of the multi-layer semiconductor structure. Alternatively, the one or more continuous lines of metal of the TSV guard ring 104 may be made of a metal different from the metallic material used in the metal layer of the multi-layer semiconductor structure. In some embodiments, the one or more continuous lines of metal of the TSV guard ring 104 may be made of copper,

Alternatively, the TSV guard ring 104 may comprise a dielectric-and-via stack that encompasses the one or more TSVs 102a-h. The TSV guard ring 104 may include one or more continuous lines of dielectric formed and embedded in one or more layers of the multi-layer semiconductor structure, and may further include one or more continuous lines of trench vias formed and embedded in one or more layers of the multi-layer semiconductor structure.

The continuous lines of dielectric and the continuous lines of trench vias are stacked alternatingly such that a continuous line of trench via is stacked between two continuous lines of dielectric, and vice versa. For example, a continuous line of dielectric may be embedded in a first layer of the multi-layer semiconductor structure while a continuous line of trench via may be embedded in a second layer of the multi-layer semiconductor structure that is adjacent the first layer. The one or more continuous lines of dielectric and the one or more continuous lines of trench vias are stacked to form a dielectric-and-via stack, or wall, one all layers of the multi-layer semiconductor structure through which the one or more TSVs 102a-h are formed, as depicted in FIG. 3. In other words, the TSV guard ring 104 is a barrier encompassing the TSV region 110, and hence the one or more TSVs 102a-h, to hermetically seal the TSV region 110 to confine moisture, contaminants and chemicals that may diffuse from the one or more TSVs 102a-h during TSV-related processing, such as etching, cleaning, plating, and so forth.

The one or more continuous lines of dielectric of the TSV guard ring 104 may be made of the same dielectric material used in the dielectric layer of the multi-layer semiconductor structure. Alternatively, the one or more continuous lines of dielectric of the TSV guard ring 104 may be made of a dielectric different from the dielectric material used in the dielectric layer of the multi-layer semiconductor structure. In some embodiments, the one or more continuous lines of dielectric of the TSV guard ring 104 may be made of high-density nitride. In some embodiments, the one or more continuous lines of dielectric of the TSV guard ring 104 may be made of silicon nitride.

As shown in FIG. 4, the TSV guard ring 104 is formed as close to the one or more TSVs 102a-h as possible. The TSV guard ring 104 forms a barrier, or wall, that encompasses the one or more TSVs 102a-h. The TSV damage monitor 106 is formed around the TSV guard ring 104 and the one or more TSVs 102a-h. The metal lines 106a(1)-(n) may be coupled in a staircase-like, or wave-like, manner. For example, as depicted in FIG. 4, a first one of the metal line 106a(1)-(n) may be embedded in a first layer of the multi-layer semiconductor structure, a second one of the metal line 106a(1)-(n) may be embedded in a second layer of the multi-layer semiconductor structure adjacent the first layer, a third one of the metal line 106a(1)-(n) may be embedded in a third layer of the multi-layer semiconductor structure adjacent the second layer, a fourth one of the metal line 106a(1)-(n) may be embedded in a fourth layer of the multi-layer semiconductor structure adjacent the third layer, a fifth one of the metal line 106a(1)-(n) may be embedded in the third layer, a sixth one of the metal line 106a(1)-(n) may be embedded in the second layer, a seventh one of the metal line 106a(1)-(n) may be embedded in the first layer, and so on.

Example Processes

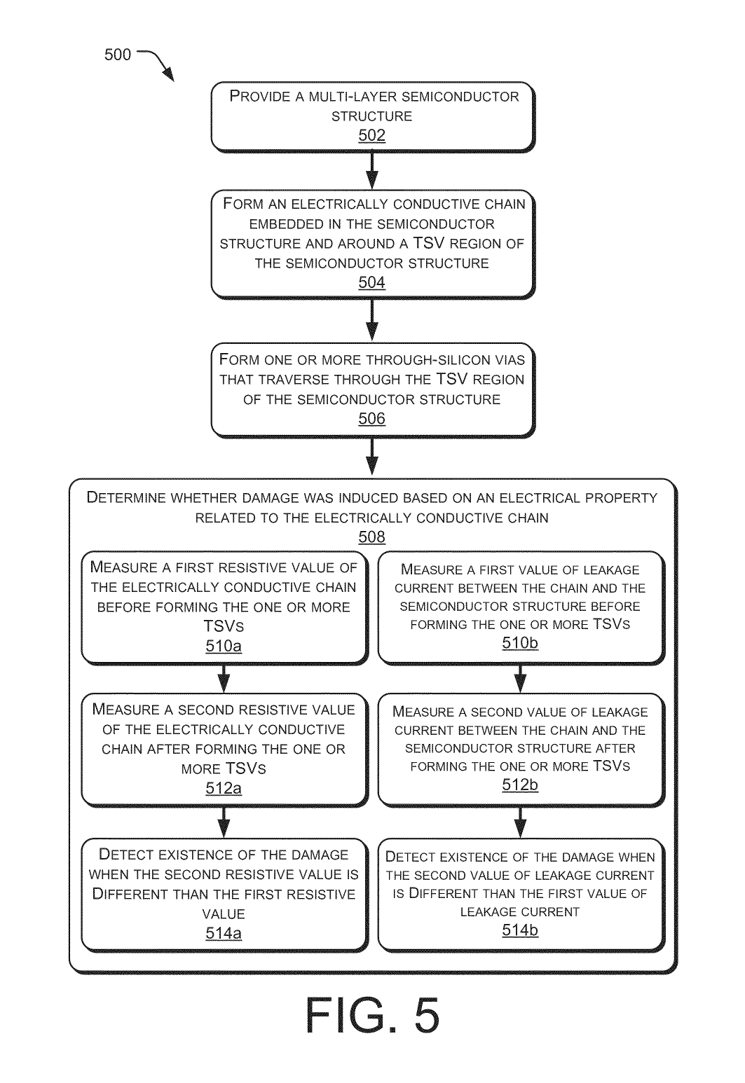

FIG. 5 is a flow chart illustrating an example process 500 that implements monitoring of damage to circuitry or structure neighboring one or more TSVs caused by TSV-related processing using a TSV damage monitor.

As shown here, the process 500 begins with operation 502, in which a multi-layer semiconductor is provided. It is to be understood that the TSV damage monitor may be part of a semiconductor structure design or may be added later before TSV are physically formed.

In operation 504, an electrically conductive chain is formed, embedded in the multi-layer semiconductor structure and around a through-silicon via region of the multi-layer semiconductor structure. For example, the electrically conductive chain of the TSV damage monitor 106 may be formed and embedded in the multi-layer semiconductor structure and around the TSV region 110.

In operation 506, one or more TSVs that traverse through the through-silicon via region of the multi-layer semiconductor structure are formed. For example, the one or more TSVs 102a-h may be formed in the TSV region 110.

The process 500 may optionally include one or more operations, such as operation 508.

In operation 508, the process 500 determines whether damage to a portion of the multi-layer semiconductor structure was induced during a process of forming the TSVs based on an electrical property related to the electrically conductive chain. For example, one or more electrical properties of the electrically conductive chain of the TSV damage monitor 106 may be measured to detect damage.

In some embodiments, the operation 508 may include operations 510a-514a. In other embodiments, the operation 508 may include operations 510b-514b.

In operation 510a, a first resistive value of the electrically conductive chain before forming the one or more TSVs is measured. For example, the resistance of the electrically conductive chain of the TSV damage monitor 106 may be measured before the one or more TSVs 102a-h are formed.

In operation 512a, a second resistive value of the electrically conductive chain after forming the one or more TSVs is measured. For example, the resistance of the electrically conductive chain of the TSV damage monitor 106 may be measured after the one or more TSVs 102a-h are formed.

In operation 514a, existence of the damage is detected when the second resistive value is different than the first resistive value. For example, damage is detected when there is an increase in the measured resistance of the electrically conductive chain of the TSV damage monitor 106.

In operation 510b, a first value of leakage current between the electrically conductive chain and a silicon substrate of the multi-layer semiconductor structure is measured before forming the one or more TSVs. For example, the leakage current between the electrically conductive chain of the TSV damage monitor 106 and the silicon substrate of the multi-layer semiconductor structure may be measured before forming the one or more TSVs 102a-h. If the TSV guard ring 104 is in place, in operation 510b, a first value of leakage current between the electrically conductive chain of the TSV damage monitor 106 and the TSV guard ring 104 may be measured before forming the one or more TSVs 102a-h.

In operation 512b, a second value of leakage current between the electrically conductive chain and the silicon substrate of the multi-layer semiconductor structure is measured after forming the one or more TSVs. For example, the leakage current between the electrically conductive chain of the TSV damage monitor 106 and the silicon substrate of the multi-layer semiconductor structure may be measured after forming the one or more TSVs 102a-h. If the TSV guard ring 104 is in place, in operation 512b, a first value of leakage current between the electrically conductive chain of the TSV damage monitor 106 and the TSV guard ring 104 may be measured after forming the one or more TSVs 102a-h.

In operation 514b, existence of the damage is detected when the second value of leakage current is different than the first value of leakage current. For example, damage is detected when there is an increase in the measured leakage current between the electrically conductive chain of the TSV damage monitor 106 and the silicon substrate or the TSV guard ring 104.

In some embodiments, the electrically conductive chain may be formed by forming a plurality of metal lines and forming a plurality of vias each of which coupling respective two of the plurality of metal lines such that the plurality of metal lines are electrically coupled in series. The plurality of metal lines may be coupled in a staircase-like matter such that the plurality of metal lines are embedded in each layer of the multi-layer semiconductor structure through which the one or more TSVs are fabricated, as depicted in FIG. 4.

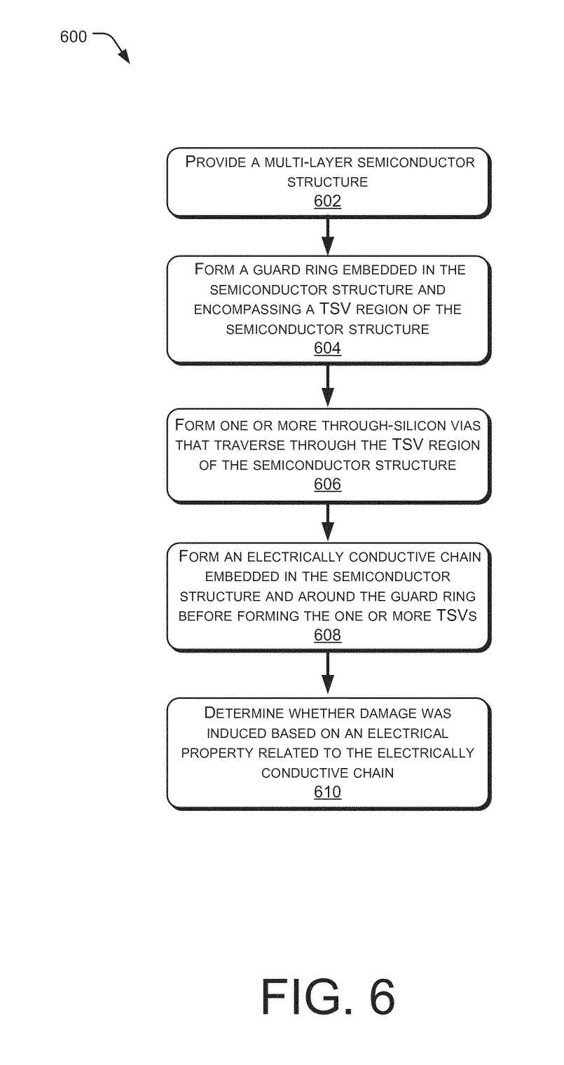

FIG. 6 is a flow chart illustrating an example process 600 that implements formation of a TSV guard ring against diffusion of moisture or chemical from one or more TSVs during TSV-related processing.

As shown here, the process 600 begins with operation 602, in which a multi-layer semiconductor is provided. It is to he understood that the TSV guard ring may be part of a semiconductor structure design or may be added later before TSV are physically formed.

In operation 604, a guard ring is formed, embedded in the multi-layer semiconductor structure and encompassing a through-silicon via region of the multi-layer semiconductor structure. For example, the metal-and-via stack or dielectric-and-via stack of the TSV guard ring 104 may be formed and embedded in the multi-layer semiconductor structure and around the TSV region 110.

In operation 606, one or more TSVs that traverse through the through-silicon via region of the multi-layer semiconductor structure are formed. For example, the one or more TSVs 102a-h may be formed in the TSV region 110.

In some embodiments, the guard ring may be formed by forming a continuous line of metal embedded in a first layer of the multi-layer semiconductor structure and forming a continuous line of via embedded in a second layer of the multi-layer semiconductor structure adjacent the first layer. Alternatively, the guard ring may be formed by forming a continuous line of dielectric embedded in a first layer of the multi-layer semiconductor structure and forming a continuous line of via embedded in a second layer of the multi-layer semiconductor structure adjacent the first layer.

In some embodiments, the guard ring is embedded in each layer of the multi-layer semiconductor structure through which the one or more TSVs are fabricated.

In some embodiments, the guard ring hermetically seals the TSVs such that moisture and contaminants related to fabrication of the TSVs are prevented from diffusing outside of the guard ring.

The process 600 may optionally include one or more operations, such as operations 608 and 610.

In operation 608, an electrically conductive chain is formed, embedded in the multi-layer semiconductor structure around the guard ring, before forming the one or more TSVs. For example, the TSV damage monitor 106 may be formed in addition to the TSV guard ring 104.

In operation 610, whether or not damage to a portion of the multi-layer semiconductor structure was induced during a process of forming the TSVs is determined based on an electrical property related to the electrically conductive chain. For example, damage may be detected according to the techniques as described above, e.g., process 500.

Additional and Alternative Implementation Notes

In the above description of example implementations, for purposes of explanation, specific numbers, materials configurations, and other details are set forth in order to better explain the present invention, as claimed. However, it will be apparent to one skilled in the art that the claimed invention may be practiced using different details than the example ones described herein. In other instances, well-known features are omitted or simplified to clarify the description of the example implementations.

The inventors intend the described example implementations to be primarily examples. The inventors do not intend these example implementations to limit the scope of the appended claims. Rather, the inventors have contemplated that the claimed invention might also be embodied and implemented in other ways, in conjunction with other present or future technologies.

The term “techniques,” for instance, may refer to one or more devices, apparatuses, systems, methods, articles of manufacture, and/or computer-readable instructions as indicated by the context described herein.

As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

These processes are illustrated as a collection of blocks in a logical flow graph, which represents a sequence of operations that can be implemented in mechanics alone or a combination with hardware, software, and/or firmware. In the context of software/firmware, the blocks represent instructions stored on one or more computer-readable storage media that, when executed by one or more processors, perform the recited operations.

Note that the order in which the processes are described is not intended to be construed as a limitation, and any number of the described process blocks can be combined in any order to implement the processes or an alternate process. Additionally, individual blocks may be deleted from the processes without departing from the spirit and scope of the subject matter described herein.

1-38. (canceled)

39. A device comprising:
a multi-layer semiconductor structure;
one or more through-silicon vias (TSVs) traversing through the multi-layer semiconductor structure; and
an electrically conductive chain embedded in the multi-layer semiconductor structure and around the one or more TSVs.

40. A device as recited in claim 39, wherein the electrically conductive chain comprises:
a plurality of metal lines; and
a plurality of vias each of which coupling respective two of the plurality of metal lines such that the plurality of metal lines are electrically coupled in series forming a series resistor.

41. A device as recited in claim 39, wherein the electrically conductive chain comprises: a plurality of metal lines, wherein the plurality of metal lines are coupled in a staircase-like matter such that the plurality of metal lines are embedded in each layer of the multi-layer semiconductor structure through which the one or more TSVs are fabricated.

42. A device as recited in claim 39 further comprising:
a guard ring embedded in the multi-layer semiconductor structure, between the one or more TSVs and the electrically conductive chain, and encompassing the one or more TSVs.

43. A device as recited in claim 39, further comprising a guard ring, wherein the guard ring comprises:
a continuous line of metal embedded in a first layer of the multi-layer semiconductor structure; and
a continuous line of via embedded in a second layer of the multi-layer semiconductor structure adjacent the first layer.

44. A device as recited in claim 39, further comprising a guard ring, wherein the guard ring comprises:
a continuous line of dielectric embedded in a first layer of the multi-layer semiconductor structure; and
a continuous line of via embedded in a second layer of the multi-layer semiconductor structure adjacent the first layer.

45. A device as recited in claim 39, further comprising a guard ring, wherein the guard ring is embedded in each layer of the multi-layer semiconductor structure through which the one or more TSVs are fabricated.

46. A device as recited in claim 39, further comprising a guard ring, wherein the guard ring hermetically seals the one or more TSVs such that moisture and contaminants related to fabrication of the TSVs are prevented from diffusing outside of the guard ring.

47. A device comprising:
a multi-layer semiconductor structure;
one or more through-silicon vias (TSVs) traversing through the multi-layer semiconductor structure; and
a guard ring embedded in the multi-layer semiconductor structure and encompassing the one or more TSVs.

48. A device as recited in claim 47, wherein the guard ring comprises:
a continuous line of metal embedded in a first layer of the multi-layer semiconductor structure; and
a continuous line of via embedded in a second layer of the multi-layer semiconductor structure adjacent the first layer.

49. A device as recited in claim 47, wherein the guard ring comprises:
a continuous line of dielectric embedded in a first layer of the multi-layer semiconductor structure; and
a continuous line of via embedded in a second layer of the multi-layer semiconductor structure adjacent the first layer.

50. A device as recited in claim 47, wherein the guard ring is embedded in each layer of the multi-layer semiconductor structure through which the one or more TSVs are fabricated.

51. A device as recited in claim 47, wherein the guard ring hermetically seals the one or more TSVs such that moisture and contaminants related to fabrication of the TSVs are prevented from diffusing outside of the guard ring.

52. A device as recited in claim 47 further comprising:
an electrically conductive chain embedded in the multi-layer semiconductor structure and around the one or more TSVs and the guard ring.

53. A device as recited in claim 47, further comprising an electrically conductive chain, wherein the electrically conductive chain comprises:
a plurality of metal lines; and
a plurality of vias each of which coupling respective two of the plurality of metal lines such that the plurality of metal lines are electrically coupled in series forming a series resistor.

54. A device as recited in claim 47, further comprising an electrically conductive chain that includes a plurality of metal lines, wherein the plurality of metal lines are coupled in a staircase-like matter such that the plurality of metal lines are embedded in each layer of the multi-layer semiconductor structure through which the one or more TSVs are fabricated.

55. A method comprising:
providing a multi-layer semiconductor structure;
forming an electrically conductive chain that is embedded in the multi-layer semiconductor structure and around a through-silicon via region of the multi-layer semiconductor structure; and
forming one or more through-silicon vias (TSVs) that traverse through the through-silicon via region of the multi-layer semiconductor structure.

56. A method as recited in claim 55 further comprising:
determining, based on an electrical property related to the electrically conductive chain, whether damage to a portion of the multi-layer semiconductor structure was induced during a process of forming the TSVs.

57. A method as recited in claim 55, further comprising determining whether damage to a portion of the multi-layer semiconductor structure was induced during a process of forming the TSVs, wherein the determining comprises:
measuring a first resistive value of the electrically conductive chain before forming the one or more TSVs;
measuring a second resistive value of the electrically conductive chain after forming the one or more TSVs; and
detecting existence of the damage when the second resistive value is different than the first resistive value.

58. A method as recited in claim 55, further comprising determining whether damage to a portion of the multi-layer semiconductor structure was induced during a process of forming the TSVs, wherein the determining comprises:
measuring a first value of leakage current between the electrically conductive chain and a silicon substrate of the multi-layer semiconductor structure before forming the one or more TSVs;
measuring a second value of leakage current between the electrically conductive chain and the silicon substrate of the multi-layer semiconductor structure after forming the one or more TSVs; and
detecting existence of the damage when the second value of leakage current is different than the first value of leakage current.

59. A method as recited in claim 55, wherein forming the electrically conductive chain comprises:
forming a plurality of metal lines; and
forming a plurality of vias each of which coupling respective two of the plurality of metal lines such that the plurality of metal lines are electrically coupled in series forming a series resistor.

60. A method as recited in claim 55, wherein forming the electrically conductive chain includes forming a plurality of metal lines, wherein the plurality of metal lines are coupled in a staircase-like matter such that the plurality of metal lines are embedded in each layer of the multi-layer semiconductor structure through which the one or more TSVs are fabricated.

61. A method as recited in claim 55 further comprising:
forming a guard ring that is embedded in the multi-layer semiconductor structure, between the one or more TSVs and the electrically conductive chain, and encompassing the one or more TSVs.

62. A method as recited in claim 55, further comprising forming a guard ring, wherein forming the guard ring comprises:
forming a continuous line of metal embedded in a first layer of the multi-layer semiconductor structure; and
forming a continuous line of via embedded in a second layer of the multi-layer semiconductor structure adjacent the first layer.

63. A method as recited in claim 55, further comprising forming a guard ring, wherein the guard ring comprises:
forming a continuous line of dielectric embedded in a first layer of the multi-layer semiconductor structure; and
forming a continuous line of via embedded in a second layer of the multi-layer semiconductor structure adjacent the first layer.

64. A method as recited in claim 55, further comprising forming a guard ring, wherein the guard ring is embedded in each layer of the multi-layer semiconductor structure through which the one or more TSVs are fabricated.

65. A method as recited in claim 55, further comprising forming a guard ring, wherein the guard ring hermetically seals the one or more TSVs such that moisture and contaminants related to fabrication of the TSVs are prevented from diffusing outside of the guard ring.

66. A method comprising:
providing a multi-layer semiconductor structure;
forming a guard ring that is embedded in the multi-layer semiconductor structure and encompassing a through-silicon via region of the multi-layer semiconductor structure; and
forming one or more through-silicon vias (TSVs) that traverse through the through-silicon via region of the multi-layer semiconductor structure.

67. A method as recited in claim 66, wherein forming the guard ring comprises:
forming a continuous line of metal embedded in a first layer of the multi-layer semiconductor structure; and
forming a continuous line of via embedded in a second layer of the multi-layer semiconductor structure adjacent the first layer.

68. A method as recited in claim 66, wherein forming the guard ring comprises:
forming a continuous line of dielectric embedded in a first layer of the multi-layer semiconductor structure; and
forming a continuous line of via embedded in a second layer of the multi-layer semiconductor structure adjacent the first layer.

69. A method as recited in claim 66, wherein the guard ring is embedded in each layer of the multi-layer semiconductor structure through which the one or more TSVs are fabricated.

70. A method as recited in claim 66, wherein the guard ring hermetically seals the one or more TSVs such that moisture and contaminants related to fabrication of the TSVs are prevented from diffusing outside of the guard ring.

71. A method as recited in claim 66 further comprising:
forming an electrically conductive chain embedded in the multi-layer semiconductor structure around the guard ring before forming the one or more TSVs.

72. A method as recited in claim 66 further comprising:
determining, based on an electrical property related to the electrically conductive chain, whether damage to a portion of the multi-layer semiconductor structure was induced during a process of forming the TSVs.

73. A method as recited in claim 66, further comprising determining whether damage to a portion of the multi-layer semiconductor structure was induced during a process of forming the TSVs, wherein the determining comprises:
measuring a first resistive value of the electrically conductive chain before forming the one or more TSVs;
measuring a second resistive value of the electrically conductive chain after forming the one or more TSVs; and
detecting damage to a portion of the multi-layer semiconductor structure induced during a process of forming the TSVs when the second resistive value is different than the first resistive value.

74. A method as recited in claim 66, further comprising determining whether damage to a portion of the multi-layer semiconductor structure was induced during a process of forming the TSVs, wherein the determining comprises:
measuring a first value of leakage current between the electrically conductive chain and the Guard ring or a silicon substrate of the multi-layer semiconductor structure before forming the one or more TSVs;
measuring a second value of leakage current between the electrically conductive chain and the Guard ring or the silicon substrate of the multi-layer semiconductor structure after forming the one or more TSVs; and
detecting damage to a portion of the multi-layer semiconductor structure induced during a process of forming the TSVs when the second value of leakage current is different than the first value of leakage current.

75. A method as recited in claim 66, further comprising forming an electrically conductive chain, wherein forming the electrically conductive chain comprises:
forming a plurality of metal lines; and
forming a plurality of vias each of which coupling respective two of the plurality of metal lines such that the plurality of metal lines are electrically coupled in series forming a series resistor.

76. A method as recited in claim 66, further comprising forming a plurality of metal lines, wherein the plurality of metal lines are coupled in a staircase-like matter such that the plurality of metal lines are embedded in each layer of the multi-layer semiconductor structure through which the one or more TSVs are fabricated.
